(19) United States
(12) Patent Application Publication
(10) Pub. No.: US 2024/0088201 A1
(43) Pub. Date: Mar. 14, 2024

(54) INTEGRATED RESISTOR

(71) Applicant: Microchip Technology Incorporated, Chandler, AZ (US)

(72) Inventor: Yaojian Leng, Vancouver, WA (US)

(73) Assignee: Microchip Technology Incorporated, Chandler, AZ (US)

(21) Appl. No.: 17/988,285

(22) Filed: Nov. 16, 2022

Related U.S. Application Data
(60) Provisional application No. 63/405,910, filed on Sep. 13, 2022.

(51) Int. Cl. H01L 23/522; H01L 23/528; H01L 27/06

(52) U.S. Cl. CPC H01L 28/24; H01L 23/5226; H01L 23/5283; H01L 27/0629

(57) ABSTRACT

An integrated resistor includes a resistor tub, a resistive element, and a dielectric liner. The resistor tub is formed from a conformal metal, and includes a laterally-extending tub base and vertically-extending tub sidewalls extending upwardly from the laterally-extending tub base, wherein the laterally-extending tub base and vertically-extending tub sidewalls define in a resistor tub interior opening. The dielectric liner is formed in the resistor tub interior opening. The resistive element is formed over the dielectric liner in the resistor tub interior opening, and includes a pair of resistor heads connected by a laterally-extending resistor body. The dielectric liner electrically insulates the resistive element from the resistor tub.

### RELATED APPLICATION

This application claims priority to commonly owned U.S. Provisional Patent Application No. 63/405,910 filed Sep. 13, 2022, the entire contents of which are hereby incorporated by reference for all purposes.

### TECHNICAL FIELD

The present disclosure relates to resistors, in particular to an integrated resistor, e.g., including a resistive element formed in a resistor tub.

### BACKGROUND

Metal film resistors (MFRs) may be formed as discrete resistor devices or alternatively formed in integrated circuits, referred to as integrated MFRs. Discrete MFRs are typically formed as axial resistors with a thin metal film (resistive element) sputtered or otherwise formed on a cylindrical, high purity ceramic body. The resistive element may comprise nickel chromium (NiCr), an alloy of tin and antimony, an alloy of gold and platinum, or tantalum nitride, for example. Discrete MFRs may provide a wide range of sheet resistance (e.g., 1Ω-1 MΩ), and generally have good tolerance, stability, and TCR (temperature coefficient of resistance) characteristics. In addition, discrete MFRs typically exhibit low noise properties and a highly linear voltage coefficient of resistance (VCR), which is generally beneficial. Therefore, discrete MFRs are often used in circuits in which tight tolerance, low temperature coefficient, and low noise properties are desired.

Integrated MFRs, for example integrated thin film resistors (TFRs), provide certain advantages over discrete MFRs, including lower cost and much smaller form factor. However, integrated MFRs typically do not provide high current capability (e.g., at least 1 A) or low sheet resistance (e.g., below 10 Ω/square) commonly provided by discrete MFRS.

There is a need for improved integrated MFRs, for example for current sensing, active filters, bridge circuits, and other applications.

### SUMMARY

Integrated resistors and methods of forming integrated resistors are provided. An integrated resistor may include a resistor tub formed from a conformal metal, a dielectric liner formed in a resistor tub interior opening defined by the resistor tub, and a resistive element formed over the dielectric liner in the resistor tub interior opening, wherein the dielectric liner electrically insulates the resistive element from the resistor tub. The resistive element may include a pair of resistor heads connected by a laterally-extending resistor body, e.g., to define a dog-bone shape of the resistive element.

Integrated resistors disclosed herein may be referred to as metal film resistors (MFRs), although the resistive element of an integrated resistor as disclosed herein may have a greater thickness than certain conventional MFRS, thus having a lower sheet resistance and thereby allowing higher current carrying capability as compared with such conventional MFRS. For example, in some examples, the resistive element of an integrated resistor as disclosed herein may have a vertical thickness of at least 0.5 μm, for example in the range of 0.5-2.0 μm. For example, an integrated resistor as disclosed herein may have a low sheet resistance (e.g., below 10 Ω/square) and high current capability (e.g., above 1 A).

In some examples, an integrated resistor may be formed concurrently with other IC structures, e.g., complementary metal-oxide-semiconductor (CMOS) transistor structures, e.g., without adding any mask operations to the baseline/background IC device manufacturing process.

One aspect provides an integrated resistor including a resistor tub, a resistive element, and a dielectric liner. The resistor tub is formed from a conformal metal, and includes a laterally-extending tub base and vertically-extending tub sidewalls extending upwardly from the laterally-extending tub base, wherein the laterally-extending tub base and vertically-extending tub sidewalls define a resistor tub interior opening. The dielectric liner is formed in the resistor tub interior opening. The resistive element is formed over the dielectric liner in the resistor tub interior opening, and includes a pair of resistor heads connected by a laterally-extending resistor body. The dielectric liner electrically insulates the resistive element from the resistor tub.

In some examples, the laterally-extending resistor body has a vertical thickness of at least 0.5 μm.

In some examples, the resistive element has a dog-bone shape.

In some examples, the conformal metal comprises tungsten.

In some examples, the resistive element comprises nickel chromium, tantalum nitride, silicon chromium, silicon carbide chrome, or titanium nitride.

In some examples, the integrated resistor includes a pair of resistor head connection elements formed in a metal interconnect layer and conductively connected to the pair of resistor heads.

In some examples, the integrated resistor is formed between a shallow trench insulation (STI) field oxide region and a metal interconnect layer.

In some examples, the integrated resistor is formed between a polysilicon layer and a metal interconnect layer.

In some examples, the integrated resistor is formed between two metal interconnect layers.

One aspect provides an integrated circuit (IC) device including an IC structure and an integrated resistor. The IC structure includes a vertically-extending contact comprising a first portion of a conformal metal layer. The integrated resistor includes a resistor tub, a resistive element, and a dielectric liner. The resistor tub comprising a second portion of the conformal metal layer, and includes a laterally-extending tub base and vertically-extending tub sidewalls extending upwardly from the laterally-extending tub base, wherein the laterally-extending tub base and vertically-extending tub sidewalls define a resistor tub interior opening. The dielectric liner is formed in the resistor tub interior opening. The resistive element is formed over the dielectric liner in the resistor tub interior opening, and includes a pair of resistor heads connected by a laterally-extending resistor body. The dielectric liner electrically insulates the resistive element from the resistor tub.

In some examples, the IC structure comprises a transistor structure and the vertically-extending contact comprises a transistor gate contact.

In some examples, the IC structure comprises an interconnect structure and the vertically-extending contact comprises an interconnect via.

In some examples, the vertically-extending contact has a lateral width in the range of 0.1-0.5 μm, and the laterally-extending resistor body of the resistive element has a lateral width in the range of 1-100 μm and a vertical thickness of at least 0.5 μm.

In some examples, the resistive element has a dog-bone shape, wherein each of the pair of resistor heads is wider in a first lateral direction than the resistor body.

In some examples, the conformal metal layer comprises tungsten, and the resistive element comprises nickel chromium, tantalum nitride, silicon chromium, silicon carbide chrome, or titanium nitride.

In some examples, the IC device includes (a) a pair of resistor head connection elements and (b) an IC device connection element formed in a common metal layer, wherein the pair of resistor head connection elements are conductively connected to the pair of resistor heads; and wherein the IC device connection element is conductively connected to the vertically-extending contact.

One aspect provides a method including forming a resistor tub opening in a dielectric region; depositing a conformal metal layer over the dielectric region and extending down into the resistor tub opening; depositing a dielectric liner over the conformal metal layer and extending down into the resistor tub opening; depositing a metal layer over the dielectric liner and extending down into the resistor tub opening; and performing a planarization process to remove upper portions of the metal layer, upper portions of the dielectric liner, and upper portions of the conformal metal, wherein a remaining portion of the conformal metal layer in the resistor tub opening defines a resistor tub, a remaining portion of the metal layer in the resistor tub opening defines a resistive element.

In some examples, the method includes forming the resistor tub opening concurrently with a contact opening formed over an integrated circuit (IC) structure, wherein the deposited conformal metal layer extends down into both the resistor tub opening and the contact opening, wherein the conformal metal (a) partially fills the resistor tub opening to define a conformal tub-shaped structure in the resistor tub opening and (b) fully fills the contact opening, and wherein a portion of the conformal metal layer remaining in the contact opening after the planarization process defines a contact.

In some examples, the contact opening has a lateral width in the range of 0.1-0.5 μm, and the resistor tub opening has a lateral width in the range of 1-100 μm.

In some examples, the method includes, after the planarization process, forming a metal layer including (a) pair of resistor head connection elements conductively connected to the pair of resistor head connection elements, and (b) an IC device connection element conductively connected to the contact.

In some examples, the pair of resistor head connection elements and the IC device connection element are formed by a damascene process.

### BRIEF DESCRIPTION OF THE DRAWINGS

Example aspects of the present disclosure are described below in conjunction with the figures, in which:

FIGS. 1A-1C show an example integrated resistor 100 formed in an IC device according to the present disclosure;

FIGS. 2A-2C show an example IC device including the example integrated resistor shown in FIGS. 1A-1C and a separate IC structure (e.g., CMOS structure);

FIGS. 3-11 illustrate an example method for forming the example IC device shown in FIGS. 2A-2C, including the example integrated resistor and example IC structure;

FIG. 12 shows an example IC device including an example integrated resistor and an example IC structure, wherein the integrated resistor is constructed between a polysilicon layer and a first metal interconnect layer; and

FIG. 13 shows an example IC device including the example integrated resistor and an example IC structure, wherein the integrated resistor is constructed between two metal interconnect layers.

It should be understood the reference number for any illustrated element that appears in multiple different figures has the same meaning across the multiple figures, and the mention or discussion herein of any illustrated element in the context of any particular figure also applies to each other figure, if any, in which that same illustrated element is shown.

### DETAILED DESCRIPTION OF THE INVENTION

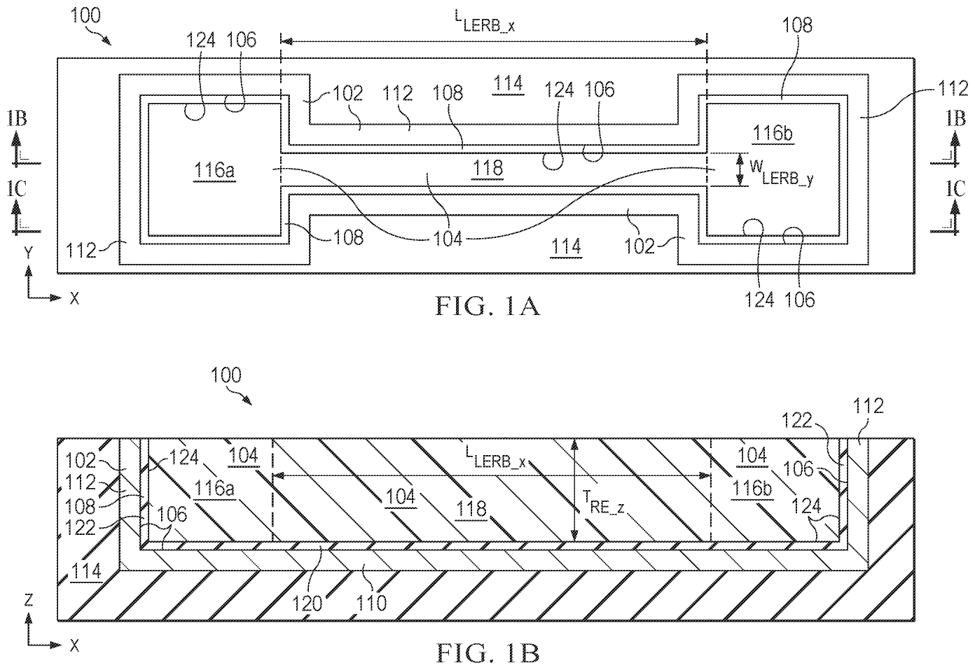

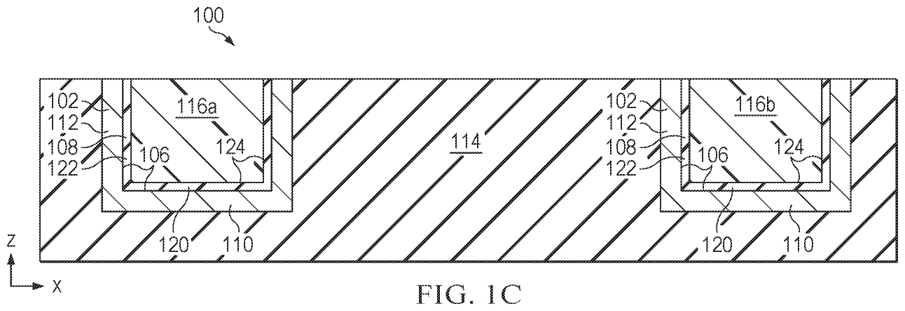

FIGS. 1A-1C show an example integrated resistor 100 formed in an integrated circuit (IC) device according to the present disclosure. In particular, FIG. 1A shows a top view of the integrated resistor 100, FIG. 1B shows a first cross-sectional side view through cut line 1B-1B shown in FIG. 1A, and FIG. 1C shows a second cross-sectional side view through cut line 1C-1C shown in FIG. 1A. As shown, integrated resistor 100 includes a resistor tub 102, a resistive element 104 formed in the resistor tub 102, and a dielectric liner 108 formed between the resistive element 104 and the resistor tub 102, wherein the dielectric liner 108 electrically insulates the resistive element 104 from the resistor tub 102. The example integrated resistor 100 may also be referred to as an integrated metal film resistor (MFR).

As discussed below in more detail, the integrated resistor 100 may be formed between a shallow trench insulation (STI) field oxide region and a first metal interconnect layer (also referred to as the Metal-1 or M₁ layer), or between a polysilicon layer and a first metal interconnect layer (i.e., Metal-1 or M₁), or between two metal interconnect layers (Mₓ and Mₓ₊₁) at any depth in the respective IC device.

The resistor tub 102 may be formed in a dielectric region 114, for example a pre-metal dielectric (PMD) region or an inter-metal dielectric (IMD) region, depending on the location of the integrated resistor 100 in the respective IC device, e.g. below a first interconnect layer (i.e., Metal-1 or M₁) or between two metal interconnect layers (Mₓ and Mₓ₊₁). In some examples dielectric region 114 comprises silicon oxide (SiO₂), phosphorus silicate glass (PSG), or borophosphosilicate glass (BPSG).

The resistor tub 102 may be formed from a conformal metal, for example tungsten (W) or other conformal metal. The resistor tub 102 has a tub shape including a laterally-extending resistor tub base 110 and vertically-extending resistor tub sidewalls 112 extending upwardly from the laterally-extending resistor tub base 110 along an outer perimeter of the laterally-extending resistor tub base 110. The vertically-extending resistor tub sidewalls 112 may extend around the full outer perimeter of the laterally-extending resistor tub base 110 to form a closed-loop structure, e.g., having a dog-bone shape as shown in FIG. 1A. The laterally-extending resistor tub base 110 and vertically-extending resistor tub sidewalls 112 collectively define a resistor tub interior opening 106 in which the dielectric liner 108 and resistive element 104 are formed.

The dielectric liner 108 is formed in the resistor tub interior opening 106 and covers interior surfaces of the resistor tub 102, including an upper surface of the laterally-extending resistor tub base 110 and inwardly-facing surfaces of the vertically-extending resistor tub sidewalls 112. In some examples, the dielectric liner may comprise silicon oxide (SiO₂), silicon nitride (SiN), or other conformal dielectric material, e.g., with a thickness in the range of 250-750 A. In the illustrated example, the dielectric liner 108 has a tub shape including a laterally-extending dielectric liner base 120 and vertically-extending dielectric liner sidewalls 122 extending upwardly from the laterally-extending dielectric liner base 120 along an outer perimeter of the laterally-extending dielectric liner base 120. The vertically-extending dielectric liner sidewalls 122 may extend around the full outer perimeter of the laterally-extending dielectric liner base 120 to form a closed-loop structure, e.g., having a dog-bone shape as shown in FIG. 1A. The laterally-extending dielectric liner base 120 and vertically-extending dielectric liner sidewalls 122 collectively define a dielectric liner interior opening 124 in which the resistive element 104 is formed.

The resistive element 104 is formed in the dielectric liner interior opening 124, or in other words, the resistive element 104 is formed over the dielectric liner 108 in the resistor tub interior opening 106. Thus, as noted above, the dielectric liner 108 is located between the resistive element 104 and the resistor tub 102 to physically separate (and thereby electrically insulate) the resistive element 104 from the resistor tub 102.

The resistive element 104 includes a pair of resistor heads 116a and 116b connected by a laterally-extending resistor body 118. In some examples, the resistor body 118 may have a lateral length L_{LERB_x} in the x-direction in the range of 1-100 μm (e.g., in the range of 5-20 μm), and a lateral width W_{LERB_y} in the y-direction in the range of 1-100 μm (e.g., in the range of 5-20 μm), where the x-direction is defined as extending between the pair of resistor heads 116a and 116b, with the y-direction being orthogonal thereto, and with a z-direction indicative of height, being orthogonal to the x-direction and the y-direction. In some examples, the laterally-extending resistor body 118 may be laterally elongated, e.g., with a length to width ratio L_{LERB_x}/W_{LERB_y} in the range of 0.1 to 100. In some examples, the resistive element 104 (e.g., including both the laterally-extending resistor body 118 and resistor heads 116a and 116b) may have a thickness T_{RE_z} in the z-direction of at least 0.5 μm, for example in the range of 0.5-2.0 μm. In some examples, the resistive element 104 is formed with a thickness T_{RE_z} in the range of 0.75-1.5 μm. The thickness T_{RE_z} of the resistive element 104 may be significantly greater than typical conventional MFRs. As a result, the integrated resistor 100 may exhibit a low sheet resistance (e.g., in the range of 1-10 Ω/square), providing high current carrying capability (e.g., above 1 A), as compared with typical conventional MFRs having a higher sheet resistance and lower current carrying capability.

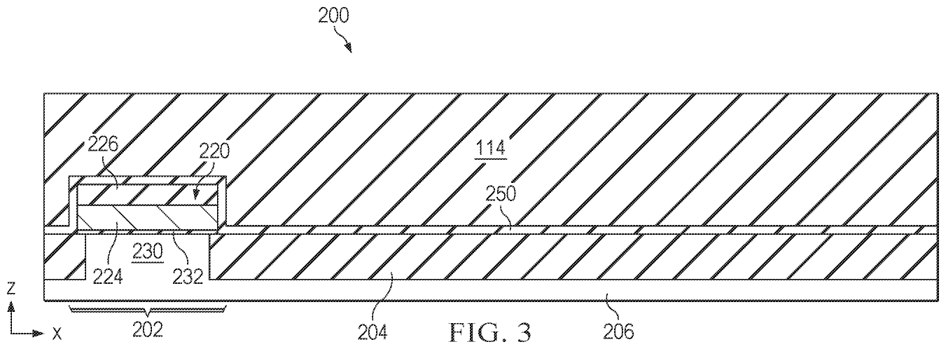

As discussed below, in some examples the integrated resistor 100 may optionally be formed (at least partially) concurrently with CMOS structures and/or other IC structures in the respective IC device including the integrated resistor 100, e.g., without adding any mask operations to the baseline/background IC device manufacturing process. For example, as discussed below with reference to FIGS. 3-10, the resistor tub 102 may be formed concurrently with vertically-extending contacts of CMOS device and/or other IC structures in the IC device, without adding any mask operations to the baseline/background IC device manufacturing process.

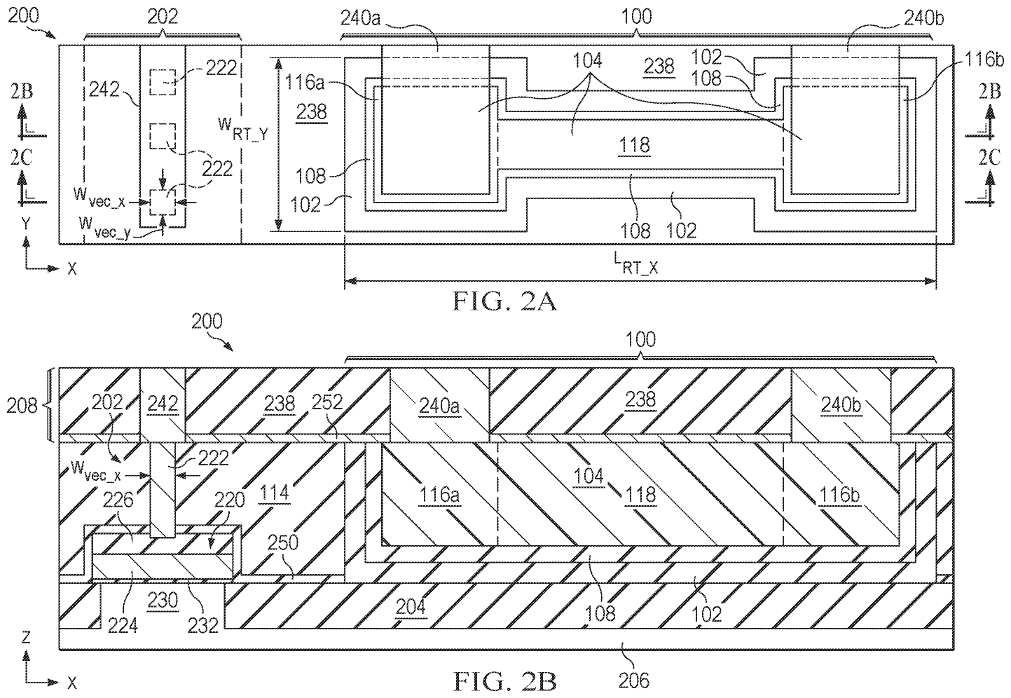

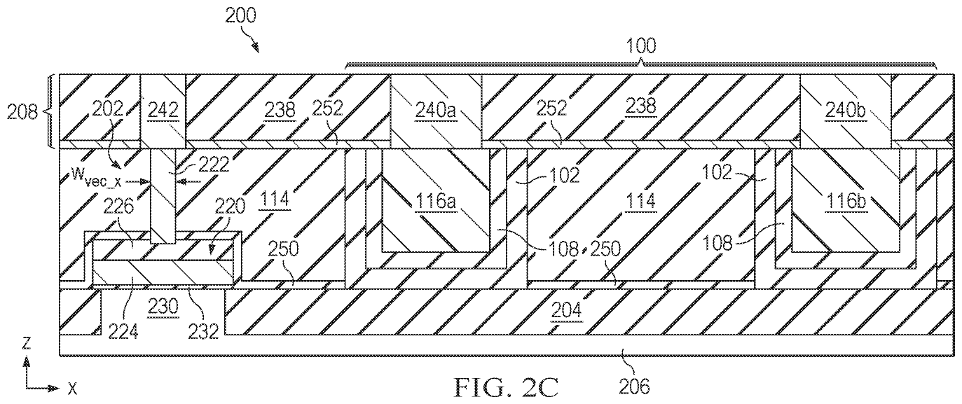

FIGS. 2A-2C show an example IC device 200 including the example integrated resistor 100 shown in FIGS. 1A-1C and a separate IC structure 202. In particular, FIG. 2A shows a top view of the example IC device 200, FIG. 2B shows a first cross-sectional side view through cut line 2B-2B shown in FIG. 2A, and FIG. 2C shows a second cross-sectional side view through cut line 2C-2C shown in FIG. 2A. In this example, the integrated resistor 100 is formed between a shallow trench insulation (STI) field oxide region 204 (e.g., formed over a silicon substrate 206) and a metal layer 208, in this example a first metal interconnect layer, also commonly referred to as a Metal-1 or M₁ layer. As shown, and discussed above regarding FIGS. 1A-1C, integrated resistor 100 includes resistor tub 102, dielectric liner 108, and resistive element 104, wherein the dielectric liner 108 is formed between the resistive element 104 and resistor tub 102 and electrically insulates the resistive element 104 from the resistor tub 102. As discussed above, the resistive element 104 includes resistor heads 116a and 116b connected by the laterally-extending resistor body 118.

The IC structure 202 may be physically distinct from the integrated resistor 100, and may include any IC structure (e.g., a structure of a transistor, resistor, capacitor, diode, or metal interconnect) including at least one element formed concurrently with at least one element of the integrated resistor 100 (e.g., from a common (same) material layer). The IC structure 202 may be at least partially formed in the dielectric region 114 in which the integrated resistor 100 is formed. For example, as discussed below, the IC structure 202 may include at least one element (e.g., at least one conductive contact) formed concurrently with the resistor tub 102, e.g., from the same conformal metal layer deposited in respective openings in the dielectric region 114.

The example IC structure 202 shown in FIGS. 2A-2C comprises a structure of a complementary metal-oxide-semiconductor (CMOS) transistor including a transistor gate 220 and at least one vertically-extending contact 222 (e.g., CMOS contact) electrically connected to the transistor gate 220. For example, as shown in FIG. 2A, the illustrated example includes three vertically-extending contacts 222 connected to the gate 220. The transistor gate 220 may comprise a silicided polysilicon structure including a polysilicon region 224 having a silicide layer 226 formed on an upper surface thereof. The transistor gate 220 may be formed over an active region (doped region) 230 of the silicon substrate 206 surrounded (laterally) by the STI field oxide region 204, wherein a gate oxide 232 is formed between the transistor gate 220 and active region 230.

As discussed in more detail below with reference to FIGS. 3-11, the vertically-extending contacts 222 (e.g., CMOS contacts) may be formed concurrently with the resistor tub 102, e.g., from a common (same) conformal metal layer (e.g., a tungsten layer) deposited in respective openings in the dielectric region 114, which may allow formation of the integrated resistor 100 without adding any additional masks to the background IC fabrication process. For example, a respective vertically-extending contact 222 may comprise a first portion of a conformal metal layer, and the resistor tub 102 may comprise a second portion of the conformal metal layer.

In some examples, vertically-extending contacts 222 respectively have a lateral width in each of the x-direction and y-direction, indicated as W_{vec_x} and W_{vec_y}, respectively, in the range of 0.1-0.5 μm. In contrast, the resistor tub 102 may be substantially larger than the vertically-extending contacts 222, e.g., in the x-direction and y-direction. For example, the resistor tub 102 may have a lateral length L_{RT_x} (x-direction) and a lateral width W_{RT_y} (y-direction) in the range of 2-100 μm.

It should be noted the terms “length” and “width” in the context of lateral dimensions (i.e., dimensions in the x-direction or y-direction) are used interchangeably herein. For example, the lateral length L_{LERB_x} of the resistor body 118 and the lateral length L_{RT_x} of the resistor tub 102 may be also referred to as a lateral widths.

The metal layer 208 may be formed in a dielectric region (e.g., IMD region) 238 formed over the resistive element 104 and vertically-extending contacts 222. The metal layer 208 may include respective metal elements conductively connected to the resistive element 104 and IC structure 202. As shown in FIGS. 2A-2C, the metal layer 208 may include (a) a pair of resistor head connection elements 240a and 240b conductively connected to the pair of resistor heads 116a and 116b, respectively, and (b) at least one IC device connection element 242 conductively connected to the vertically-extending contacts 222. The resistor head connection elements 240a and 240b and IC device connection element(s) 242 may comprise discrete metal pads, elongated metal lines, or any other shape.

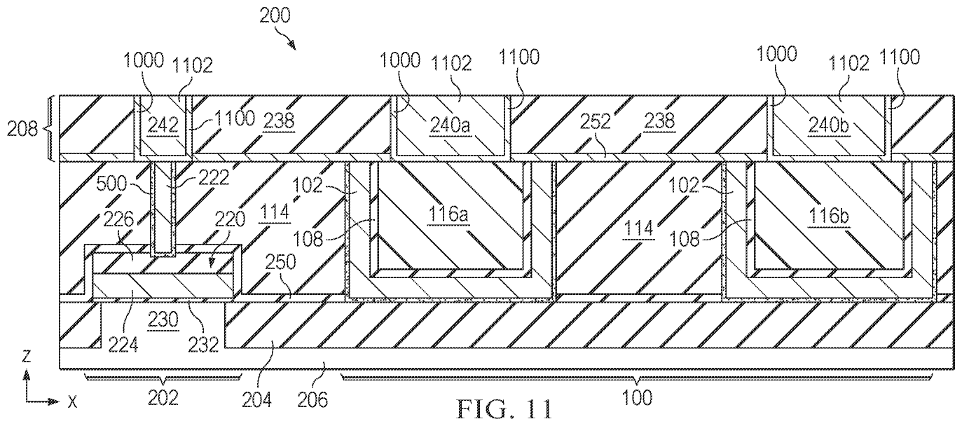

In some examples, the metal layer 208 may comprise copper, aluminum, or other metal, and the dielectric region (e.g., IMD region) 238 may comprise silicon oxide (SiO₂), fluorosilicate glass (FSG), organosilicate glass (OSG), or porous OSG. In some examples, the connection elements 240a and 240b and IC device connection element(s) 242 may be formed over an (optional) barrier layer formed in respective openings in the dielectric region (e.g., IMD region) 238, e.g., as discussed below with reference to FIG. 11.

In some examples, optional etch stop layers may be formed between respective dielectric regions. For example, as shown in FIGS. 2B and 2C, the example IC device 200 may include (a) an optional contact etch stop layer 250 formed over the STI field oxide region 204 and extending over the transistor gate 220 and/or (b) a metal etch stop layer 252 formed over the resistive element 104 and vertically-extending contacts 222 to facilitate formation of the metal layer 208.

FIGS. 3-11 illustrate an example method for forming the example IC device 200 shown in FIGS. 2A-2C, including the example integrated resistor 100 and example IC structure 202 (e.g., CMOS structure).

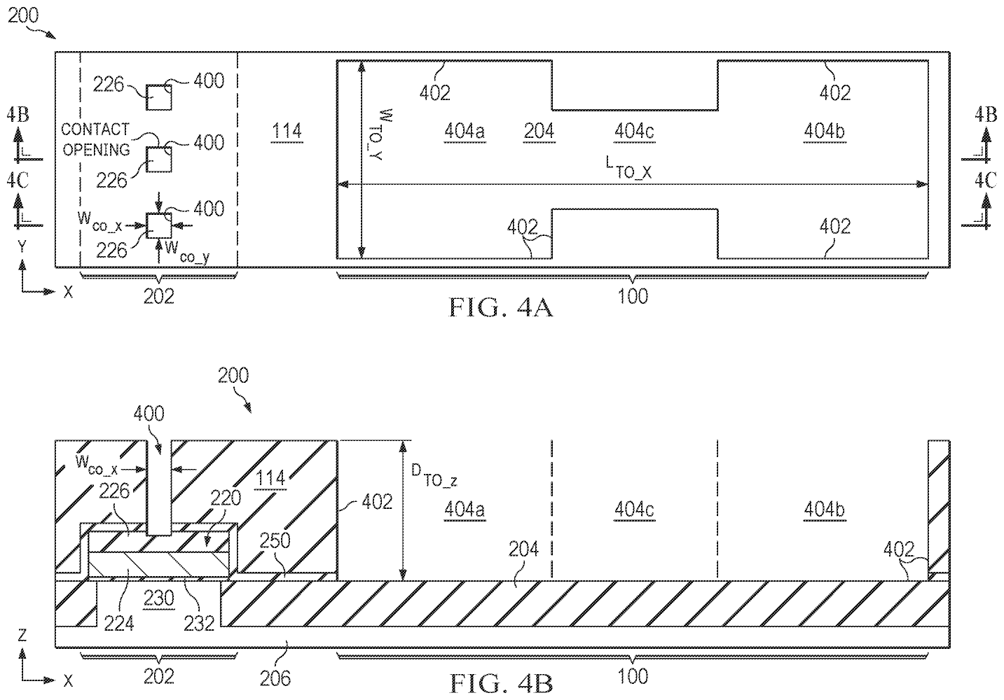

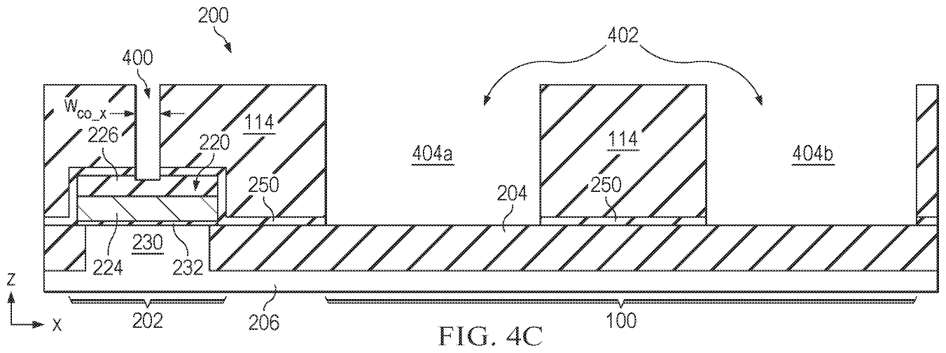

As shown in FIG. 3, the gate oxide 232 is formed on the active region 230 of the silicon substrate 206 surrounded (laterally) by the STI field oxide region 204, followed by formation of the transistor gate 220 comprising the polysilicon region 224 having a silicide layer 226 formed thereon. The optional contact etch stop layer 250 may be deposited over the STI field oxide region 204 and extend over the transistor gate 220. In some examples, the optional contact etch stop layer 250 may comprise a silicon nitride (SiN) layer deposited by plasma-enhanced chemical vapor deposition (PECVD) or other suitable deposition process, e.g., with a thickness in the range of 250-750 A. The optional contact etch stop layer 250 may facilitate the subsequent contact etch discussed below with reference to FIGS. 4A-4C.

The dielectric region 114 (e.g., PMD region) is deposited over the STI field oxide region 204 (or over the optional contact etch stop layer 250, if present), followed by a planarization process, e.g., a chemical mechanical planarization (CMP) process to planarize the top of the dielectric region 114. In some examples, the dielectric region 114 may comprise silicon oxide (SiO₂), phosphorus silicate glass (PSG), borophosphosilicate glass (BPSG), or any combination thereof.

As shown in FIGS. 4A-4C (where FIG. 4A shows a top view, FIG. 4B shows a first cross-sectional side view through cut line 4B-4B shown in FIG. 4A, and FIG. 4C shows a second cross-sectional side view through cut line 4C-4C shown in FIG. 4A), contact openings 400 (for respective vertically-extending contacts 222) and a resistor tub opening 402 (for the resistor tub 102) are patterned and etched in the dielectric region 114, which etch may be referred to as a contact etch. If present, the optional contact etch stop layer 250 may facilitate control of the contact etch, e.g., to allow the etch to stop on the contact etch stop layer 250 and subsequently advance through the contact etch stop layer 250 with improved process control (e.g., as compared to an example without the optional contact etch stop layer 250), e.g., to prevent the etch from penetrating through the silicide layer 226 of the transistor gate 220, which penetration may cause high contact resistance or high transistor leakage.

In some examples, contact openings 400 respectively have a lateral width in each of the x-direction and y-direction, indicated as W_{co_x} and W_{co_y}, respectively, in the range of 0.1-0.5 μm. In contrast, the resistor tub opening 402 may have a lateral length L_{TO_x} (x-direction) and a lateral width W_{TO_y} (y-direction) in the range of 2-100 μm. In some examples, the resistor tub opening 402 may have a vertical depth D_{TO_z} (z-direction) of at least 0.75 μm, for example in the range of 0.75-2.0 μm. In some examples, the resistor tub opening 402 has a depth D_{TO_z} in the range of 0.8-1.0 μm.

As shown in FIG. 4A, the resistor tub opening 402 may have a dog-bone shape including a pair of resistor head opening regions 404a and 404b (in which the resistor heads 116a and 116b are subsequently formed) connected by a laterally-extending resistor body opening region 404c (in which the laterally-extending resistor body 118 is subsequently formed).

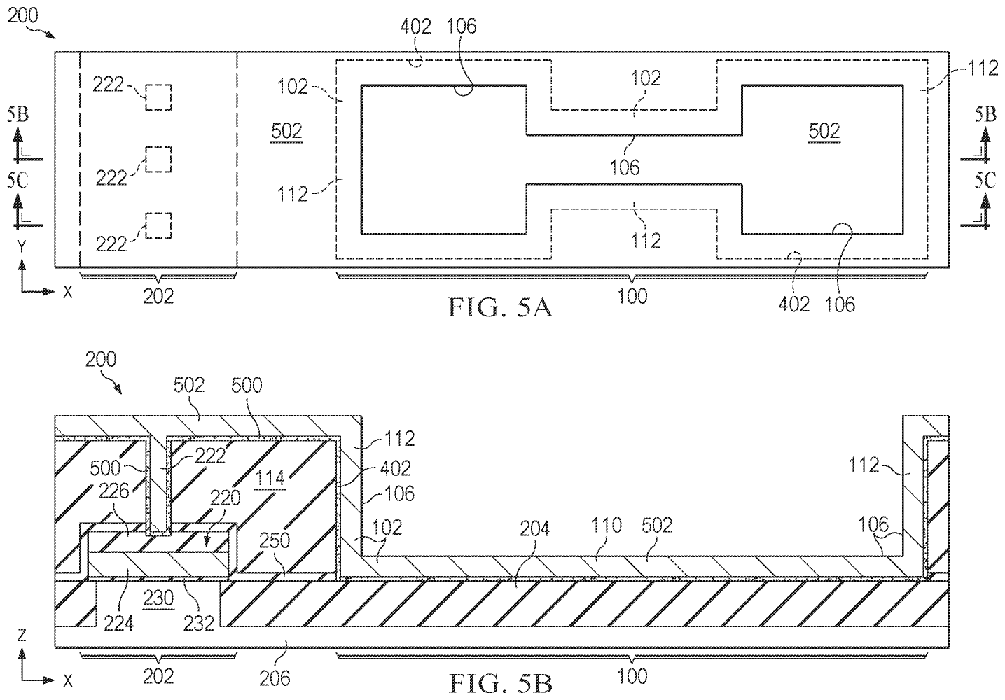

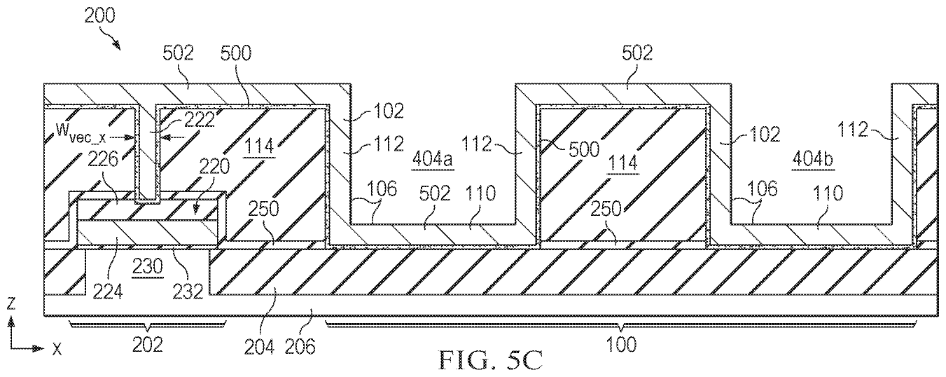

As shown in FIGS. 5A-5C (where FIG. 5A shows a top view, FIG. 5B shows a first cross-sectional side view through cut line 5B-5B shown in FIG. 5A, and FIG. 5C shows a second cross-sectional side view through cut line 5C-5C shown in FIG. 5A), a liner or glue layer 500 (e.g., a TiN liner) may be deposited over the dielectric region 114 and extending down into the contact openings 400 and resistor tub opening 402. A conformal metal layer 502 may be deposited over the liner 500 and extending down into the contact openings 400 and resistor tub opening 402. In some examples the conformal metal layer 502 comprises tungsten (W) deposited by PECVD or other suitable deposition process with a thickness of less than 5000 A, e.g., in the range of 1000-5000 A, and in some examples in the range of 2000-3000 A. The conformal metal layer 502 may completely fill the respective contact openings 400 to define respective vertically-extending contacts 222, and partially fill the resistor tub opening 402 to define the resistor tub 102 in the resistor tub opening 402. Accordingly, the conformal metal layer 502 enables the concurrent formation of the vertically-extending contacts 222 and the resistor tub 102.

As discussed above, the resistor tub 102 has a tub shape including the laterally-extending resistor tub base 110 and vertically-extending resistor tub sidewalls 112 extending upwardly from the laterally-extending resistor tub base 110 along an outer perimeter (e.g., in the x-y plane shown in FIG. 5A) of the laterally-extending resistor tub base 110. The vertically-extending resistor tub sidewalls 112 extend around the full outer perimeter of the laterally-extending resistor tub base 110 to form a closed-loop structure having a dog-bone shape as shown in FIG. 5A. The laterally-extending resistor tub base 110 and vertically-extending resistor tub sidewalls 112 collectively define the resistor tub interior opening 106 in which the dielectric liner 108 and resistive element 104 are subsequently formed.

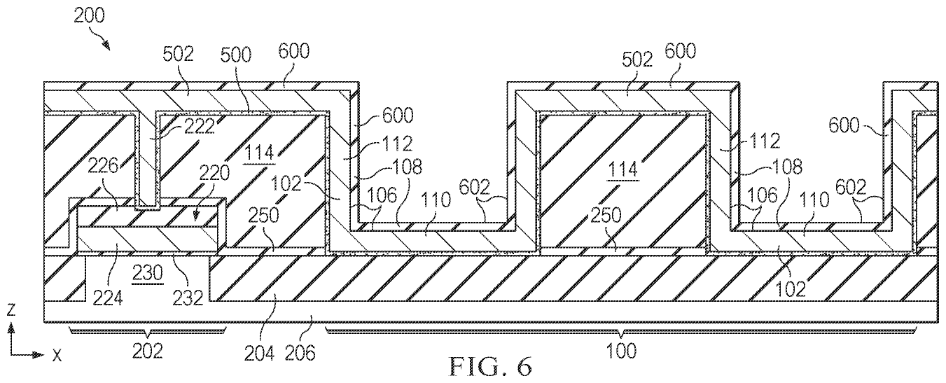

As shown in FIG. 6, a dielectric liner layer 600 is deposited over the conformal metal layer 502 and extending down into the resistor tub interior opening 106 to define the dielectric liner 108 in the resistor tub interior opening 106. As shown, the dielectric liner 108 covers interior surfaces of the resistor tub 102, including an upper surface of the laterally-extending resistor tub base 110 and inwardly-facing surfaces of the vertically-extending resistor tub sidewalls 112. The dielectric liner 108 defines a (dog-bone shaped) dielectric liner opening 602 in the resistor tub interior opening 106. In some examples, the dielectric liner may comprise silicon oxide (SiO₂), silicon nitride (SiN), or other conformal dielectric material, deposited by PECVD or other suitable deposition process, e.g., with a thickness in the range of 250-750 A.

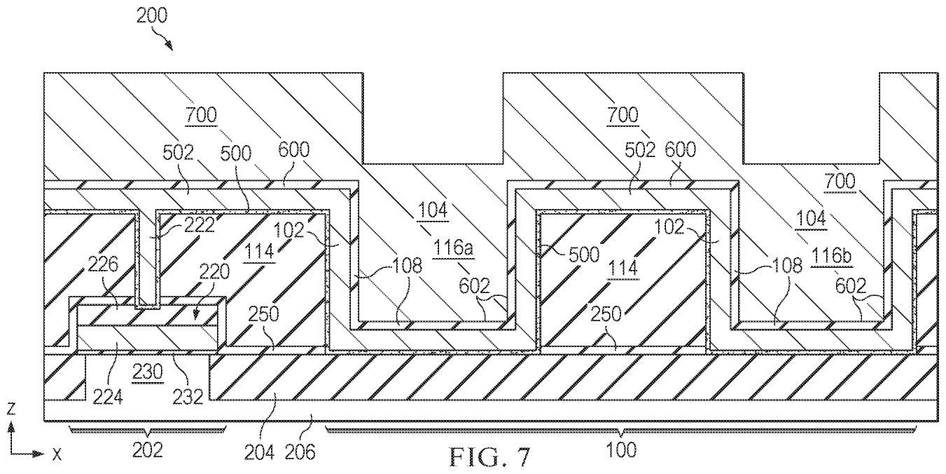

As shown in FIG. 7, a resistive element metal layer 700 is deposited over the dielectric liner layer 600 and extending down into the dielectric liner opening 602 to define the dog-bone shaped resistive element 104 (including the pair of resistor heads 116a and 116b connected by the laterally-extending resistor body 118) in the dielectric liner opening 602. (It should be noted that resistor body 118 is not shown in the cross-sectional view of FIG. 7). In some examples, the resistive element metal layer 700 may comprise nickel chromium (NiCr), tantalum nitride (TaN), silicon chromium (SiCr), silicon carbide chrome (SiCCr), titanium nitride (TiN), or other metal. The resistive element metal layer 700 may be deposited by physical vapor deposition (PVD) or other deposition process, e.g., with sufficient thickness to fill the dielectric liner opening 602.

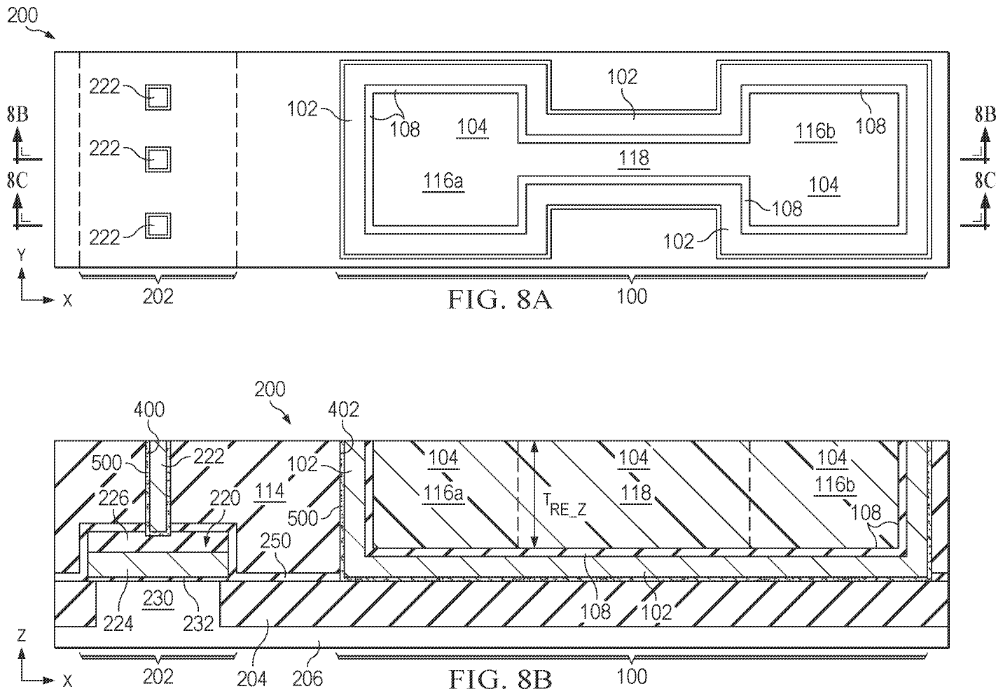

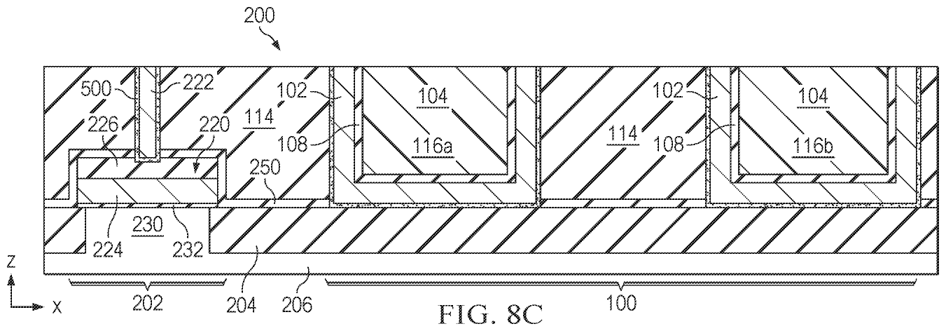

As shown in FIGS. 8A-8C (where FIG. 8A shows a top view, FIG. 8B shows a first cross-sectional side view through cut line 8B-8B shown in FIG. 8A, and FIG. 8C shows a second cross-sectional side view through cut line 8C-8C shown in FIG. 8A), a planarization process (e.g., a CMP process) is performed to remove upper portions of the resistive element metal layer 700, dielectric liner layer 600, conformal metal layer 502, and liner 500 extending outside (i.e., above) the contact openings 400 and resistor tub opening 402, leaving (a) the resistor tub 102, dielectric liner 108, and resistive element 104 in the resistor tub opening 402 and (b) vertically-extending contacts 222 in respective contact openings 400. As discussed above, in some examples, the planarized resistive element 104 may have a thickness T_{RE_z} in the z-direction of at least 0.5 μm, for example in the range of 0.5-2.0 μm, and in some examples, in the range of 0.5-0.7 μm.

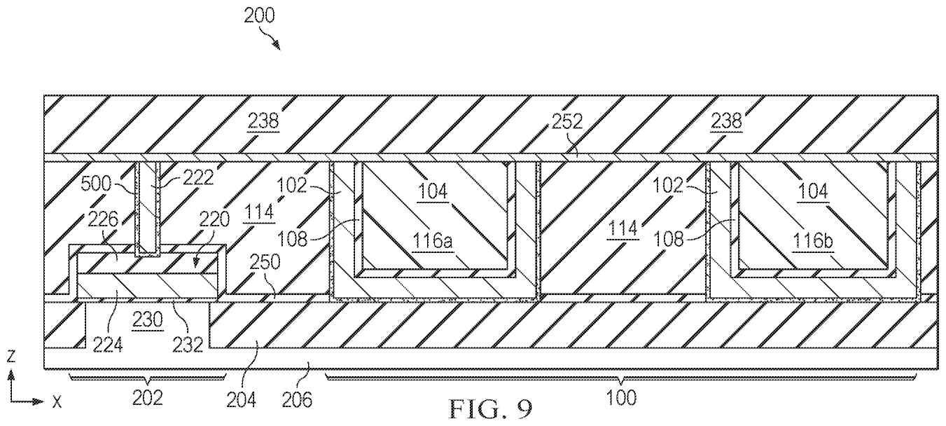

As shown in FIGS. 9-11, the metal layer 208 is formed over the structure shown in FIGS. 8A-8C, the metal layer 208 including (a) the resistor head connection elements 240a and 240b conductively connected to the pair of resistor heads 116a and 116b, respectively, and (b) IC device connection element 242 conductively connected to vertically-extending contacts 222.

As shown in FIG. 9, the metal etch stop layer 252 may be formed over the dielectric region 114, resistive element 104, and vertically-extending contacts 222, to facilitate formation of the metal layer 208. The metal etch stop layer 252 may comprise silicon nitride (SiN) or silicon carbide (SiC), e.g., with a thickness in the range of 250-750 A. The dielectric region (e.g., IMD region) 238 may be formed over the metal etch stop layer 25. In some examples, the dielectric region 238 may comprise silicon oxide (SiO₂), fluorosilicate glass (FSG), organosilicate glass (OSG), or porous OSG.

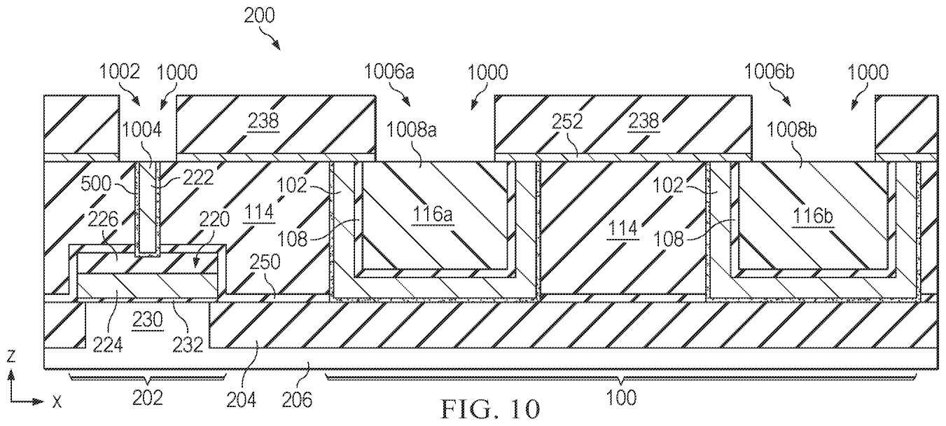

As shown in FIG. 10, trench patterning and trench etching processes may be performed to form metal layer openings 1000 extending though the dielectric region (IMD region) 238 and underlying metal etch stop layer 252. The metal layer openings 1000 may include (a) IC device connection element opening 1002 exposing upper surfaces 1004 of vertically-extending contacts 222 (e.g., CMOS contacts), (b) a pair of resistor head connection element openings 1006a and 1006b exposing upper surfaces 1008a and 1008b, respectively, of the resistor heads 116a and 116b.

As shown in FIG. 11, the IC device connection element 242 and resistor head connection elements 240a and 240b are formed. In one example, a conductive barrier layer 1100 (e.g., a tantalum/tantalum nitride (Ta/TaN) bilayer) is deposited in the metal layer openings 1000, followed by a copper seed deposition, a copper plating process, a copper anneal process, and a planarization (e.g., CMP) process, to form (a) the IC device connection element 242 in IC device connection element opening 1002 and (b) the resistor head connection elements 240a and 240b in the resistor head connection element openings 1006a and 1006b, respectively. The IC device connection element 242 is conductively connected to vertically-extending contacts 222, e.g., through respective portions of the conductive barrier layer 1100, and the resistor head connection elements 240a and 240b are conductively connected to the resistor heads 116a and 116b, respectively, through respective portions of the conductive barrier layer 1100.

After forming the example integrated resistor 100 as described above, the background IC fabrication process may continue, e.g., to construct respective CMOS interconnect structures.

The sheet resistance R of a metal film resistor (MFR) may be represented by the equation:

R=(ρ*L)/(H*W) (1)
wherein ρ represents resistivity, and H, L, and W represent the dimensions of the MFR, in particular the height H (vertical thickness), length L (in a first lateral direction), and width W (in a second lateral direction) of the MFR. For the example integrated resistor 100, Equation (1) may be written as:

R=(ρ*L_{LERB_x})/(W_{LERB_y}*T_{RE_z}) (2)

For example, according to Equation (2), an instance of integrated resistor 100 in which (a) the resistive element 104 is formed from nickel chromium (NiCr), having a resistivity of 1.10×10⁻⁶ Ωm, and (b) the laterally-extending resistor base 118 has a thickness T_{RE_z} of 1.0 μm and a length/width ratio L_{LERB_x}/W_{LERB_y}=1, has a sheet resistance R of 1.1 ohm/square.

In some examples, the various parameters of integrated resistor 100 (e.g., parameters represented in Equation (2) above) provide a sheet resistance R of less than 10 ohm/square, for example in the range of 1-10 ohm/square, which is lower than certain conventional MFRs. Accordingly, the example integrated resistor 100 may provide high current carrying capability (e.g., at least 1 A) as compared with certain conventional MFRs.

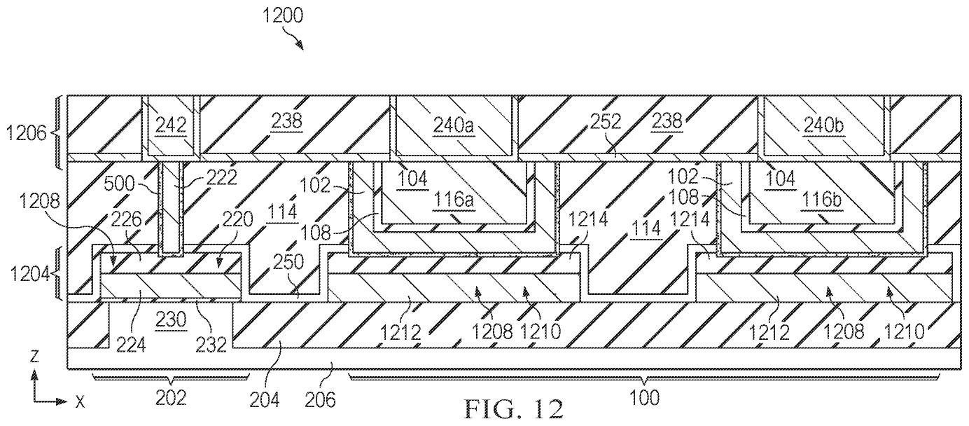

FIG. 12 shows an example IC device 1200 including the example integrated resistor 100 and the example IC structure 202, wherein the integrated resistor 100 is constructed between a polysilicon layer 1204 and a metal layer 1206, e.g., a first metal interconnect layer (also referred to as a Metal-1, or M₁ layer). The metal layer 1206 may include (a) resistor head connection elements 240a and 240b conductively connected to the pair of resistor heads 116a and 116b, respectively, and (b) IC device connection element 242 conductively connected to vertically-extending contacts 222.

The polysilicon layer 1204 may be a silicided polysilicon layer (including silicided polysilicon structures) or a non-silicided polysilicon layer (including non-silicided polysilicon structures). In the example shown in FIG. 12 the polysilicon layer 1204 is a silicided polysilicon layer including multiple silicided polysilicon structures 1208, wherein respective silicided polysilicon structures 1208 include a respective polysilicon structure having a silicide region formed on an upper surface thereof.

In the example shown in FIG. 12, the silicided polysilicon structures 1208 formed in the polysilicon layer 1204 include the transistor gate 220 (discussed above) and a resistor tub base 1210 on which the resistor tub 102 is formed. As discussed above, the transistor gate 220 may comprise a polysilicon region 224 having a silicide layer 226 formed on an upper surface thereof. As discussed above, the transistor gate 220 may be formed over the active region 230 laterally surrounded by the STI field oxide region 204, wherein a gate oxide 232 is formed between the transistor gate 220 and active region 230. Similarly, the resistor tub base 1210 may comprise a polysilicon region 1212 having a silicide layer 1214 formed on an upper surface thereof. As shown, an optional contact etch stop layer 250 may be formed over the STI field oxide region 204 and extending over the transistor gate 220 and the resistor tub base 1210.

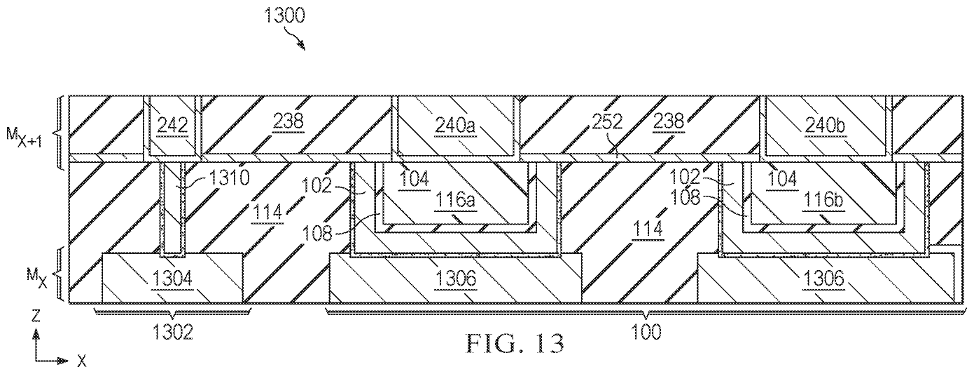

FIG. 13 shows an example IC device 1300 including the example integrated resistor 100 and an example IC structure 1302, wherein the integrated resistor 100 is constructed between a lower metal interconnect layer Mₓ and an upper metal interconnect layer Mₓ₊₁, e.g., at any depth in the IC device 1300. The lower metal interconnect layer Mₓ may include metal elements including a lower metal IC structure element (e.g., interconnect element) 1304 and a resistor base 1306. A vertically-extending contact (e.g., interconnect via) 1310 may be formed on, and electrically connected to, the lower metal IC structure element (e.g., interconnect element) 1304, and the resistor tub 102 may be formed on the resistor base 1306. The upper metal interconnect layer Mₓ₊₁ may include (a) resistor head connection elements 240a and 240b conductively connected to the pair of resistor heads 116a and 116b, respectively, and (b) an upper metal IC interconnect element 242 conductively connected to vertically-extending contact (e.g., interconnect via) 1310. The lower metal interconnect layer Mₓ and upper metal interconnect layer Mₓ₊₁ may be formed from any suitable metal or metals, e.g., copper, aluminum, or other metal(s).

1. An integrated resistor, comprising:
a resistor tub formed from a conformal metal, the resistor tub including a laterally-extending tub base and vertically-extending tub sidewalls extending upwardly from the laterally-extending tub base, wherein the laterally-extending tub base and vertically-extending tub sidewalls define a resistor tub interior opening;
a dielectric liner formed in the resistor tub interior opening; and
a resistive element formed over the dielectric liner in the resistor tub interior opening, the resistive element including a pair of resistor heads connected by a laterally-extending resistor body,
wherein the dielectric liner electrically insulates the resistive element from the resistor tub.

2. The integrated resistor of claim 1, wherein the laterally-extending resistor body has a vertical thickness of at least 0.5 μm.

3. The integrated resistor of claim 1, wherein the resistive element has a dog-bone shape.

4. The integrated resistor of claim 1, wherein the conformal metal comprises tungsten.

5. The integrated resistor of claim 1, wherein the resistive element comprises nickel chromium, tantalum nitride, silicon chromium, silicon carbide chrome, or titanium nitride.

6. The integrated resistor of claim 1, comprising a pair of resistor head connection elements formed in a metal interconnect layer and conductively connected to the pair of resistor heads.

7. The integrated resistor of claim 1, wherein the integrated resistor is formed between a shallow trench insulation (STI) field oxide region and a metal interconnect layer.

8. The integrated resistor of claim 1, wherein the integrated resistor is formed between a polysilicon layer and a metal interconnect layer.

9. The integrated resistor of claim 1, wherein the integrated resistor is formed between two metal interconnect layers.

10. An integrated circuit (IC) device, comprising:
an IC structure including a vertically-extending contact comprising a first portion of a conformal metal layer; and
an integrated resistor comprising:
a resistor tub comprising a second portion of the conformal metal layer, the resistor tub including a laterally-extending tub base and vertically-extending tub sidewalls extending upwardly from the laterally-extending tub base, wherein the laterally-extending tub base and vertically-extending tub sidewalls define a resistor tub interior opening;
a dielectric liner formed in the resistor tub interior opening; and
a resistive element formed over the dielectric liner in the resistor tub interior opening, the resistive element including a pair of resistor heads connected by a laterally-extending resistor body,
wherein the dielectric liner electrically insulates the resistive element from the resistor tub.

11. The IC device of claim 10, wherein the IC structure comprises a transistor structure and the vertically-extending contact comprises a transistor gate contact.

12. The IC device of claim 10, wherein the IC structure comprises an interconnect structure and the vertically-extending contact comprises an interconnect via.

13. The IC device of claim 10, wherein:
the vertically-extending contact has a lateral width in the range of 0.1-0.5 μm; and
the laterally-extending resistor body of the resistive element has a lateral width in the range of 1-100 μm and a vertical thickness of at least 0.5 μm.

14. The IC device of claim 10, wherein:
the conformal metal layer comprises tungsten; and
the resistive element comprises nickel chromium, tantalum nitride, silicon chromium, silicon carbide chrome, or titanium nitride.

15. The IC device of claim 10, comprising (a) a pair of resistor head connection elements and (b) an IC device connection element, formed in a common metal layer;
wherein the pair of resistor head connection elements are conductively connected to the pair of resistor heads; and
wherein the IC device connection element is conductively connected to the vertically-extending contact.

16. A method, comprising:
forming a resistor tub opening in a dielectric region;
depositing a conformal metal layer over the dielectric region and extending down into the resistor tub opening;
depositing a dielectric liner over the conformal metal layer and extending down into the resistor tub opening;
depositing a metal layer over the dielectric liner and extending down into the resistor tub opening; and
performing a planarization process to remove upper portions of the metal layer, upper portions of the dielectric liner, and upper portions of the conformal metal;
wherein a remaining portion of the conformal metal layer in the resistor tub opening defines a resistor tub, and a remaining portion of the metal layer in the resistor tub opening defines a resistive element.

17. The method of claim 16, comprising forming the resistor tub opening with a vertical depth of at least 0.75 μm.

18. The method of claim 16, comprising:
forming the resistor tub opening concurrently with a contact opening formed over an integrated circuit structure; and
wherein the deposited conformal metal layer extends down into both the resistor tub opening and the contact opening, wherein the conformal metal (a) partially fills the resistor tub opening to define a conformal tub-shaped structure in the resistor tub opening and (b) fully fills the contact opening,
wherein a portion of the conformal metal layer remaining in the contact opening after the planarization process defines a contact conductively connected to the integrated circuit structure.

19. The method of claim 18, wherein:
the contact opening has a lateral width in the range of 0.1-0.5 μm; and
the resistor tub opening has a lateral width in the range of 1-100 μm.

20. The method of claim 18, comprising after the planarization process, forming a metal layer including (a) pair of resistor head connection elements conductively connected to the pair of resistor head connection elements, and (b) an IC device connection element conductively connected to the contact.
